(19) United States
(12) Patent Application Publication
(10) Pub. No.: US 2025/0240003 A1
(43) Pub. Date: Jul. 24, 2025

(54) LOW POWER AND LOW NOISE CONTINUOUS-TIME COMPARATOR

(71) Applicant: QUALCOMM Incorporated, San Diego, CA (US)

(72) Inventors: David Ta-hsiang LIN, San Diego, CA (US); Yuhua GUO, San Diego, CA (US)

(21) Appl. No.: 18/421,852

(22) Filed: Jan. 24, 2024

(51) Int. Cl. H03K 5/24; H03M 3/00; H04M 1/60

(52) U.S. Cl. CPC H03K 5/2472; H03M 3/464; H04M 1/6008

(57) ABSTRACT

A comparator is provided with an always-on current source that conducts a bias current through the comparator. The comparator asserts a comparator output signal in response to a ramp signal being greater than a threshold voltage. To increase the comparator speed while maintaining a relatively low power consumption, the comparator includes a boost current source that conducts a boost current through the comparator only during an enable period that begins when the ramp signal is greater than a duty cycle voltage that is less than the threshold voltage.

### TECHNICAL FIELD

The present application relates generally to comparators, and more specifically to a low power and low noise continuous-time comparator.

### BACKGROUND

A continuous-time comparator is an analog device that detects when a signal exceeds a threshold voltage and is a fundamental building block in numerous circuit applications. Since continuous-time comparators are so common and fundamental, the following discussion will refer to them simply as comparators for brevity. An important operating parameter for a comparator is its propagation delay, which is the delay between an input signal to the comparator and an output signal from the comparator. It can be shown that the propagation delay is a function of a bias current conducted by the comparator such that the greater the bias current, the smaller is the propagation delay. In addition, a relatively large bias current reduces transistor noise within the comparator. Conversely, the smaller the bias current, the greater is the propagation delay and transistor noise. A comparator designer is thus faced with either reduced power consumption but a relatively large propagation delay and increased transistor noise or a relatively small propagation delay and reduced transistor noise at the price of increased power consumption.

### SUMMARY

In accordance with an aspect of the disclosure, a comparator system is provided that includes: a ramp signal generator configured to periodically generate a ramp signal; an auxiliary comparator configured to assert an enable signal in response to the ramp signal being greater than a duty cycle voltage; a main comparator configured to assert a comparator output signal in response to the ramp signal being greater than a threshold voltage that is greater than the duty cycle voltage, wherein the main comparator includes: an always-on current source configured to conduct a bias current throughout a period of the ramp signal; and a boost current source configured to conduct a boost current only while the enable signal is asserted.

In accordance with another aspect of the disclosure, a method of operation for a comparator is provided that includes: periodically generating a ramp signal; conducting a bias current through the comparator throughout a period of the ramp signal; conducting a boost current through the comparator in response to the ramp signal being greater than a duty cycle voltage; and asserting an output signal of the comparator in response to the ramp signal being greater than a threshold voltage that is greater than the duty cycle voltage.

Finally, in accordance with yet another aspect of the disclosure, a comparator is provided that includes: a power supply node for a power supply voltage; an always-on current source coupled to the power supply node; a first switch coupled to the power supply node; a boost current source coupled to the first switch; a first PMOS transistor having a source coupled to the always-on current source and to the boost current source; a first NMOS transistor having a drain coupled to a drain of the first PMOS transistor, wherein a gate of the first PMOS transistor is coupled to a gate of the first NMOS transistor; a second PMOS transistor having a source coupled to the always-on current source and to the boost current source; a second NMOS transistor having a drain coupled to a drain of the second PMOS transistor, wherein a gate of the second PMOS transistor is coupled to a gate of the second NMOS transistor; and a third NMOS transistor having a source coupled to ground, a gate coupled to the drain of the second NMOS transistor, and a drain coupled to a source of the first NMOS transistor and to a source of the second NMOS transistor.

These and other advantageous features may be better appreciated through the following detailed description.

### BRIEF DESCRIPTION OF THE DRAWINGS

FIG. 1 is a diagram of a sigma-delta analog-to-digital converter including a current digital-to-analog converter that is clocked by a system including a low power and low noise comparator in accordance with an aspect of the disclosure.

FIG. 2 is a diagram of a system including a low noise and low power comparator in accordance with an aspect of the disclosure.

FIG. 3 is a diagram of several operating waveforms for the system of FIG. 2 in accordance with an aspect of the disclosure.

FIG. 4 is a circuit diagram of a low noise and low power comparator in accordance with an aspect of the disclosure.

FIG. 5 is a flowchart of a method of operation for a low power and low noise comparator in accordance with an aspect of the disclosure.

FIG. 6 illustrates some example electronic systems including a low noise and low power comparator in accordance with an aspect of the disclosure.

Implementations of the present disclosure and their advantages are best understood by referring to the detailed description that follows. It should be appreciated that like reference numerals are used to identify like elements illustrated in one or more of the figures.

### DETAILED DESCRIPTION

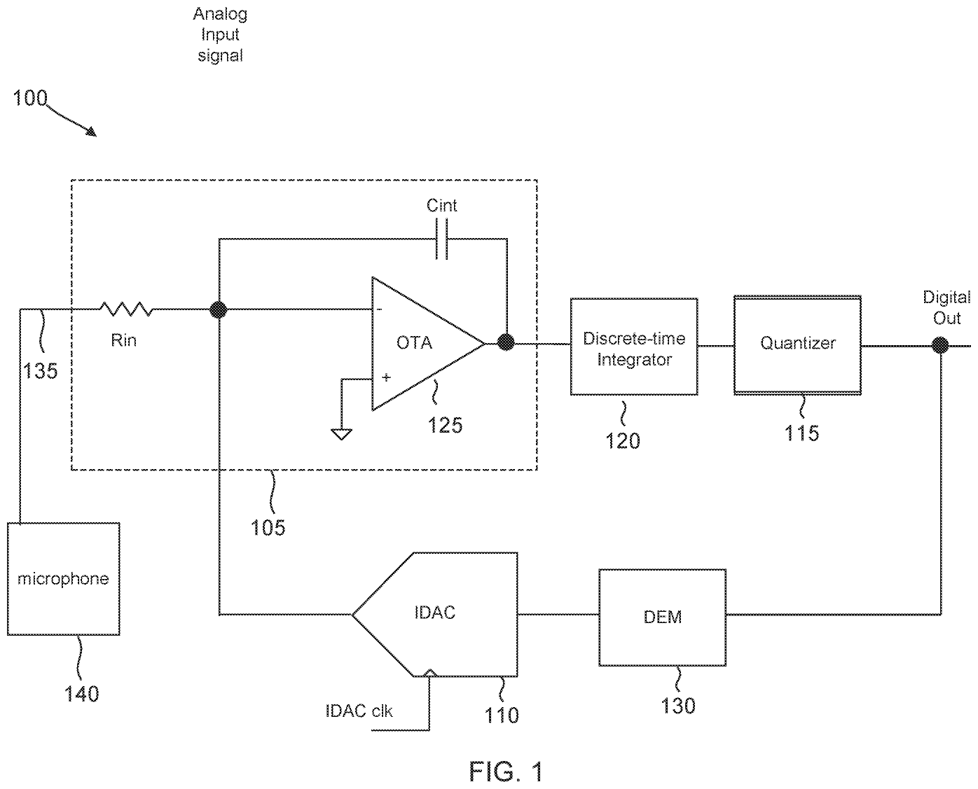

A comparator is disclosed herein that is high speed and low noise yet has a relatively small power consumption. The resulting low power and low noise comparator may be used in any system that uses a comparator. An example system that benefits from such a comparator is a sigma-delta analog-to-digital converter (ADC) 100 as shown in FIG. 1. A first integration stage 105 is a continuous-time integration stage that integrates according to a resistor-capacitor (RC) time constant. An input resistor Rin functions as the R in the RC time constant. An input signal being quantized such as an audio signal from a micro-electromechanical system (MEMS) microphone 140 drives an input terminal 135 of the input resistor whereas another terminal of the input resistor couples to an inverting terminal of a differential amplifier such as an operational transconductance amplifier (OTA) 125. An integration capacitor that functions as the C in the RC time constant couples between the inverting terminal and an output terminal of the OTA 125. The time constant thus equals Rin*Cint, where Rin is the resistance of the input resistor and Cint is the capacitance of the integration capacitor. A feedback current digital-to-analog converter (IDAC) 110 also drives the inverting terminal. To reduce jitter sensitivity, it is advantageous to form the IDAC as a return-to-zero IDAC that pulses current according to an integration pulse width (Tp) within a cycle of an IDAC clock signal (IDAC clk).

A discrete-time integrator 120 integrates an output signal from the first integration stage 105 to provide an integrated signal that is quantized by a quantizer 115 to provide a digital output signal. After processing by a dynamic element matching function 130, the digital output signal feeds back through the IDAC to the inverting node of the OTA 125. For improved performance of the sigma-delta ADC 100, the IDAC clock signal that clocks the IDAC 110 should have a relatively low amount of jitter.

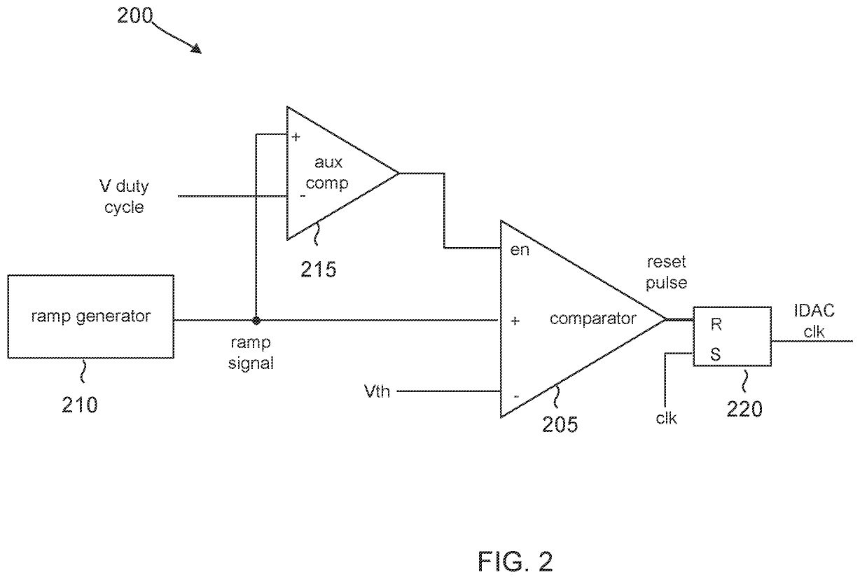

A comparator system 200 as shown in FIG. 2 advantageously provides a low jitter IDAC clock signal through the use of a low power and low noise comparator 205 as disclosed herein. However, it will be that the comparator system 200 may be used in any suitable comparator application. Comparator 205 receives a ramp signal from a ramp signal generator 210 at a non-inverting input terminal. Comparator 205 compares the ramp signal to a threshold voltage (Vth) received at an inverting input terminal to generate a reset pulse to a set-reset (SR) latch 220. Traditionally, comparator 205 would have to choose between a relatively low propagation delay with reduced transistor noise but at the cost of higher power consumption or lower power consumption but a relatively large propagation delay and increased transistor noise as discussed earlier. However, comparator 205 also receives an enable signal at an enable input terminal from an auxiliary comparator 215. As will be explained further herein, comparator 205 is configured to conduct a relatively small bias current until the enable signal is asserted, whereupon comparator 205 conducts a significantly larger boost current in addition to the bias current so as to have increased performance and operating speed at a trip point when the ramp signal rises to equal and become greater than the threshold voltage. Comparator 205 is also denoted herein as a main comparator.

The delay between the assertion of the enable signal and the trip point of the comparator 205 is large enough so that the boost current in the comparator 205 may begin conducting sufficiently prior to the trip point yet the delay is not excessively large so as to limit the resulting power consumption. The increased bias current advantageously reduces transistor noise so that the comparator 205 may generate a comparator output signal having reduced jitter. The delay between the assertion of the enable signal and the trip point is determined by the time between a trip point of the auxiliary comparator 215 and the trip point of the comparator 205. In one implementation, the ramp signal frequency may range from 500 KHz to several MHz (e.g., greater 6 MHZ) such that the delay may be approximately 20 nano-seconds but it will be appreciated that other ramp signal frequencies and delay values may be used in alternative implementations. With respect to the trip point of the auxiliary comparator 215, the auxiliary comparator 215 receives the ramp signal at a non-inverting input terminal and receives a duty cycle voltage signal (V duty cycle) at an inverting input terminal. The trip point of the auxiliary comparator 215 thus occurs when the ramp signal increases so as to exceed the duty cycle voltage signal.

The duty cycle voltage signal is sufficiently smaller than the threshold voltage signal so that the desired delay between the trip point of the auxiliary comparator 215 and the main comparator 205 is provided. The faster the ramp signal frequency, the greater should be the difference between the voltage threshold and the duty cycle voltage. Conversely, as the ramp signal frequency is reduced, the difference between the voltage threshold and the duty cycle voltage may be reduced.

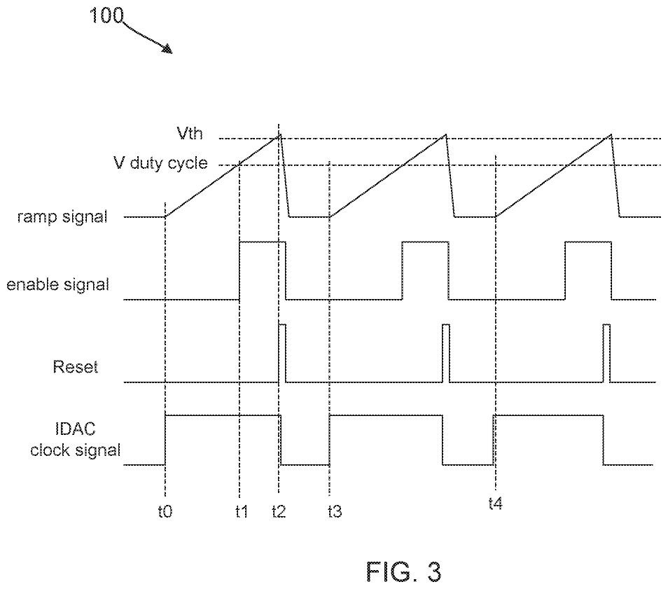

Prior to the reset of the SR latch 220 by the main comparator 205, an internal clock signal (clock) sets the SR latch 220 to cause the SR latch to pulse the IDAC clock to the IDAC 125. When the main comparator 205 reaches its trip point and asserts the reset signal, the SR latch resets (discharges) the IDAC clock signal. To provide a better appreciation of the comparator system 200, some of its operating waveforms are shown in FIG. 3. In a first cycle of the IDAC clock signal, the internal clock (clk) signal (FIG. 2) is asserted, which causes the setting of the IDAC clock signal at a time to. The internal clock signal also triggers the ramp signal generator 210 to begin ramping up the ramp signal at time t0 from a default value such as zero volts. The ramp signal increases so as to exceed the duty cycle voltage, which causes the auxiliary comparator 215 to assert the enable signal at a time t1. The ramp signal continues to increase until it reaches or exceeds the threshold voltage at a time t2, which causes the main comparator 205 to pulse the reset signal. The pulsing of the reset signal causes the ramp signal and the enable signal to both be reset (discharged to their default value) and also causes the reset of the IDAC clock signal. These waveforms repeat in a second cycle of the ramp signal beginning at a time t3 and in a third cycle of the ramp signal beginning at a time t4.

The pulse width of the enable signal equals the delay between the trip point of the auxiliary comparator 215 and the trip point of the main comparator 205. This pulse width may also be denoted as a duty cycle that is determined by the difference between the threshold voltage and the duty cycle voltage. Should the ramp signal frequency be increased, the slope of the ramp signal (the amount of increase of the ramp signal per a given unit of time) will increase accordingly. It may be seen from FIG. 3 that the difference between the threshold voltage and the duty cycle voltage should then be increased so that the desired duty cycle of the enable signal may be maintained. Conversely, if the ramp signal frequency is decreased, the difference between the threshold voltage and the duty cycle voltage may be decreased so that the desired duty cycle of the enable signal is maintained.

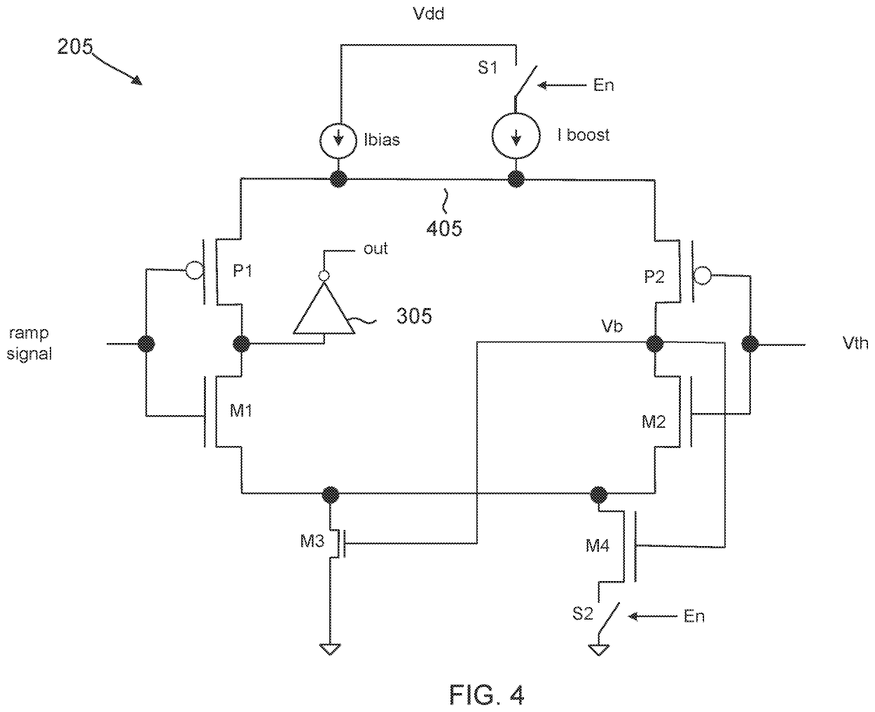

Referring again to the comparator system 200, the auxiliary comparator 215 is traditional in that it is both low power but has a relatively large propagation delay and increased transistor noise. In contrast, the main comparator 205 is low power yet has a relatively small propagation delay and reduced transistor noise. A circuit diagram for an example implementation of the main comparator 205 that provides these advantages is shown in FIG. 4. A supply-side always-on current source (Ibias) couples between a power supply node for a power supply voltage VDD and a source of a p-type metal-oxide semiconductor (PMOS) transistor P1 and a source of a PMOS transistor P2. A drain of the transistor P1 couples to a drain of an n-type metal-oxide semiconductor (NMOS) transistor M1. Similarly, a drain of the transistor P2 couples to a drain of an NMOS transistor M2. The sources of transistors M1 and M2 couple to ground through an NMOS transistor M3.

A node for the ramp signal couples to the gates of transistors P1 and M1. Similarly, a node for the threshold voltage (Vth) couples to the gates of transistors P2 and M2. An inverter 305 inverts the drain voltage of transistors P1 and M1 to produce a comparator output signal (out). In the comparator system 200, a comparator output signal from the main comparator 205 functions as the reset pulse to reset the SR latch 220. However, it will be appreciated that the main comparator 205 may be used in any system that uses a low power and low noise continuous-time comparator. With regard to the operation of the main comparator 205, suppose that the ramp signal has not risen to equal the duty cycle voltage (prior to time t1 of FIG. 2). Since the ramp signal will then be considerably less than the threshold voltage, the bias current conducted by the always-on current source will flow largely through transistors P2 and M2 as compared to transistors P1 and M1. The drain of transistor P1 will thus be charged towards the power supply voltage VDD such that the comparator output signal is grounded (a binary zero in a binary-high implementation). A drain voltage of the transistors P2 and M2 will rise to substantially equal a voltage Vb. The drains of the transistors P2 and M2 couple to a gate of transistor M3. The gate of transistor M3 is thus charged to the voltage Vb to switch transistor M3 fully on. Transistor M3 may thus also be denoted herein as a first self-biased transistor. Because of the self-biasing of transistor M3 by the voltage Vb, the bias current from the always-on current source conducts substantially through transistors P2 and M2 and transistor M3 to ground prior to time t1.

The always-on current source is configured or sized such that the bias current is relatively small to conserve power. But recall that the transistor noise of a comparator is increased as the bias current is reduced. Thus, if the main comparator 205 merely included the always-on current source, a jitter in the output signal of the main comparator 205 may be undesirably large. To reduce the propagation delay and transistor noise, the main comparator 205 includes a supply-side boost current source (Iboost) that sources a relatively large boost current. But unlike the always-on current source, the boost current source couples to the power supply node through a switch SI that closes only when the enable signal is asserted. Prior to time t1, switch S1 is open such that the boost current source cannot supply the boost current. From time t1 to time t2, switch S1 is closed such that the boost current source can drive the boost current to the sources of transistors P1 and P2. The sources of transistors P1 and P2 thus couple to a shared current source output node 405 of the always-on current source and of the boost current source. In an alternative implementation, the switch S1 may instead couple between the boost current source and the sources of transistors P1 and P2.

Note that the transistor M3 is relatively small and could thus be overloaded by the sudden conduction of both the bias current and the boost current. The sources of transistors M3 and M4 thus couple to a drain of an NMOS transistor M4 that is larger than transistor M3. A source of transistor M4 couples to ground through a switch S2 configured to switch on with the assertion of the enable signal. In an alternative implementation, switch S2 may instead couple between the drain of transistor M4 and the sources of transistors M1 and M2. Prior to time t1, switch S2 is off such that transistor M4 cannot conduct any current. But from time t1 to time t2, switch S2 is on to allow transistor M4 to conduct. The gate of transistor M4 is coupled to the drains of transistor P2 and M2 to charge the gate of transistor M4 to the common-mode voltage Vb. Transistor M4 may thus also be denoted herein as a second self-biased transistor in that it is biased by the common-mode voltage Vb. From time t1 to time t2, transistor M4 in conjunction with transistor M3 conduct the sum of the bias current and the boost current to ground. As the ramp signal rises above the threshold voltage, the drain voltage of transistor M1 will drop below a trip point for the inverter 305 such that the comparator output signal is asserted. This assertion of the comparator output signal causes the ramp signal and the enable signal to both reset. The resetting of the enable signal opens up switches S1 and S2 so that the boost current stops conducting to ground. The resetting of the ramp signal causes the comparator output signal to reset (discharge to ground), whereupon another ramp signal cycle may repeat.

Transistors P1 and M1 may also be denoted herein as a first pair of transistors that couple between the current source output node 405 and the drains of transistors M3 and M4. Similarly, transistors P2 and M2 may also be denoted herein as a second pair of transistors that couple between the current source output node 405 and the drains of transistors M3 and M4.

The pulsing of the boost current only from time t1 to time t2 is relatively short such that the power consumption is limited yet the comparator speed is advantageously increased prior to the trip point of the main comparator 205. The bias current is also relatively small so as to reduce power consumption but keep the voltage Vb at an appropriate level for accurate operation.

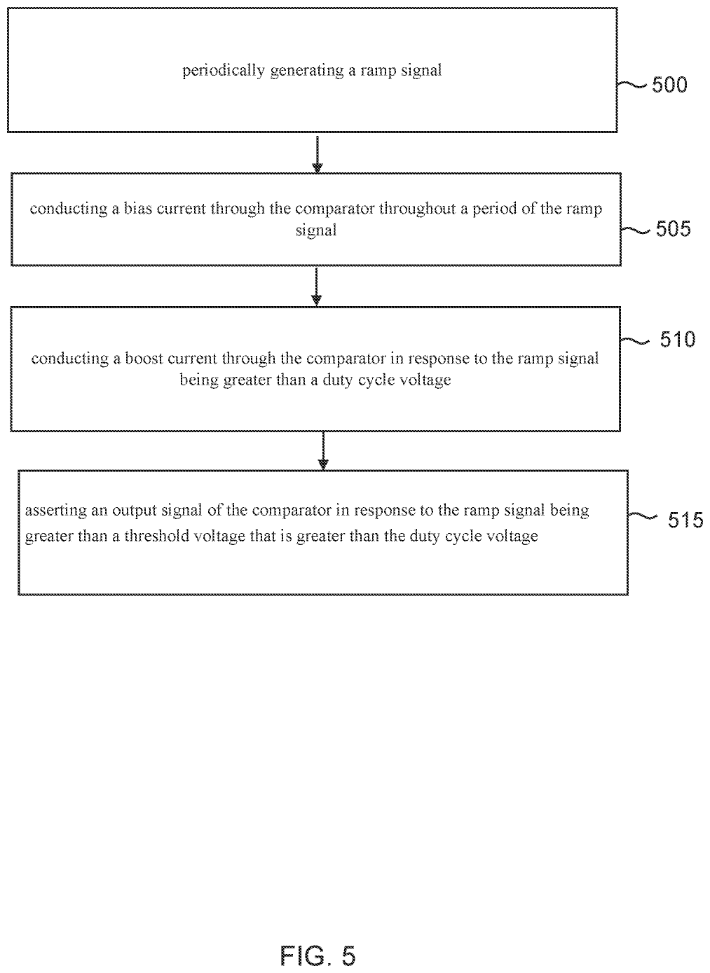

A method of operation for a low noise and low power comparator as disclosed herein will now be discussed with reference to the flowchart of FIG. 5. The method includes an act 500 of periodically generating a ramp signal. The periodic generation of the ramp signal by the ramp generator 210 as shown in FIG. 2 is an example of act 500. The method also includes an act 505 of conducting a bias current through the comparator throughout a period of the ramp signal. The generation of the bias current by the always-on current source Ibias in the main comparator 205 is an example of act 505. In addition, the method includes an act 510 of conducting a boost current through the comparator in response to the ramp signal being greater than a duty cycle voltage. The conduction of the boost current through the main comparator 205 while the enable signal is asserted is an example of act 510. Finally, the method includes an act 515 of asserting an output signal of the comparator in response to the ramp signal being greater than a threshold voltage that is greater than the duty cycle voltage. The assertion of the reset signal as discussed with regard to FIG. 3 is an example of act 515.

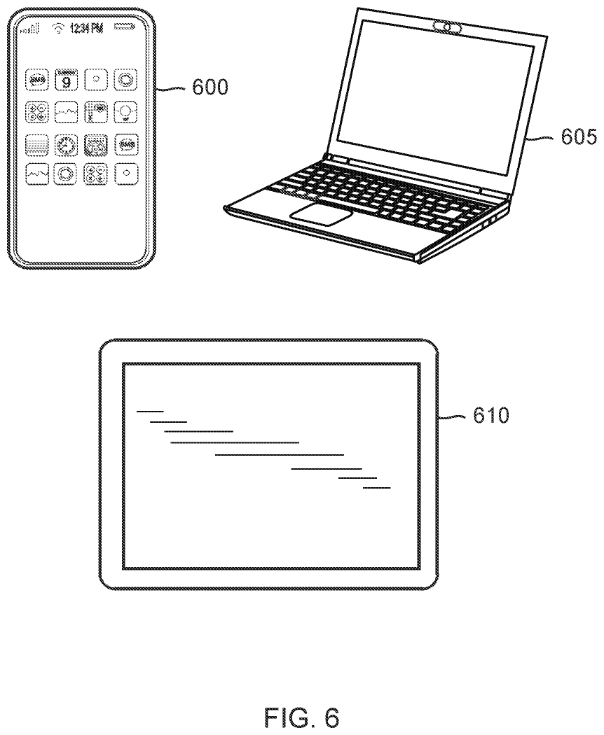

A low power and low noise comparator such as the main comparator 205 disclosed herein may be incorporated in a wide variety of electronic systems. For example, as shown in FIG. 6, a cellular telephone 600, a laptop computer 605, and a tablet PC 610 may each include a MEMS microphone producing an audio signal that is digitized by an analog-to-digital converter including a low power and low noise comparator in accordance with the disclosure. Other exemplary electronic systems such as a music player, a video player, a communication device, and a personal computer may also be configured with a low power and low noise comparator constructed in accordance with the disclosure.

The disclosure will now be summarized through the following example clauses:

Clause 1. A comparator system, comprising:
a ramp signal generator configured to periodically generate a ramp signal;
an auxiliary comparator configured to assert an enable signal in response to the ramp signal being greater than a duty cycle voltage;
a main comparator configured to assert a comparator output signal in response to the ramp signal being greater than a threshold voltage that is greater than the duty cycle voltage, wherein the main comparator includes:
an always-on current source configured to conduct a bias current throughout a period of the ramp signal; and
a boost current source configured to conduct a boost current only while the enable signal is asserted.
   Clause 2. The comparator system of clause 1, wherein the main comparator further includes:
a power supply node for a power supply voltage; and
a first switch configured coupled to the power supply node and configured to close only while the enable signal is asserted, wherein the always-on current source is coupled to the power supply node and wherein the first switch is coupled between the power supply node and the boost current source.
   Clause 3. The comparator system of clause 2, wherein the main comparator further includes:
a first self-biased transistor having a source coupled to ground;
a first pair of transistors coupled in series between a current source output node of both the always-on current source and the boost current source and a drain of the first self-biased transistor; and
a second pair of transistors coupled in series between the current source output node and the drain of the first self-biased transistor, wherein a gate of the first self-biased transistor is coupled to a node between the transistors in the second pair of transistors.
   Clause 4. The comparator system of any of clauses 2-3, wherein the main comparator further comprises:
a second self-biased transistor having a drain coupled to the drain of the first self-biased transistor and having a gate coupled to the node between the transistors in the second pair of transistors; and
a second switch coupled between a source of the second self-biased transistor and ground, wherein the second switch is configured to close only while the enable signal is asserted.
   Clause 5. The comparator system of any of clauses 2-4, wherein the first pair of transistors comprises:
a first p-type metal-oxide semiconductor (PMOS) transistor having a source coupled to the current source output node; and
a first n-type metal-oxide semiconductor (NMOS) transistor having a drain coupled to a drain of the first PMOS transistor and having a source coupled to a drain of the first self-biased transistor and to a drain of the second self-biased transistor.
   Clause 6. The comparator system of any of clauses 4-5, wherein the second pair of transistors comprises:
a second PMOS transistor having a source coupled to the current source output node; and
a second NMOS transistor having a drain coupled to a drain of the second PMOS transistor and having a source coupled to a drain of the first self-biased transistor and to a drain of the second self-biased transistor.
   Clause 7. The comparator system of clause 5, wherein a gate of the first PMOS transistor and a gate of the first NMOS transistor are both coupled to a node for the ramp signal.
   Clause 8. The comparator system of clause 6, wherein a gate of the second PMOS transistor and a gate of the second NMOS transistor are both coupled to a node for the duty cycle voltage.
   Clause 9. The comparator system of clause 5, wherein the main comparator further comprises:
an inverter configured to invert a voltage of the drain of the first PMOS transistor to provide the comparator output signal.
   Clause 10. The comparator system of any of clauses 1-9, further comprising:
a set-reset latch configured to reset a clock signal to a current digital-to-analog converter in response to an assertion of the comparator output signal.
   Clause 11. The comparator system of clause 10, wherein the current digital-to-analog converter in included in a sigma-delta analog-to-digital converter.
   Clause 12. The comparator system of any of clauses 1-11, wherein the comparator system is included within an analog-to-digital converter configured to digitize an audio signal from a micro-electromechanical system (MEMS) microphone.
   Clause 13. A method of operation for a comparator, comprising:
periodically generating a ramp signal;
conducting a bias current through the comparator throughout a period of the ramp signal;
conducting a boost current through the comparator in response to the ramp signal being greater than a duty cycle voltage; and
asserting an output signal of the comparator in response to the ramp signal being greater than a threshold voltage that is greater than the duty cycle voltage.
   Clause 14 The method of clause 13, further comprising:
resetting a clock to a current digital-to-analog converter in a sigma-delta analog digital converter responsive to an assertion of the output signal of the comparator.
   Clause 15. The method of any of clauses 13-14, further comprising:
stopping a conduction of the boost current through the comparator in response to the ramp signal being greater than the threshold voltage.
   Clause 16. The method of any of clause 13-15, wherein the boost current is larger than the bias current.
   Clause 17. A comparator comprising:
a power supply node for a power supply voltage;
an always-on current source coupled to the power supply node;
a first switch coupled to the power supply node;
a boost current source coupled to the first switch;
a first PMOS transistor having a source coupled to the always-on current source and to the boost current source;
a first NMOS transistor having a drain coupled to a drain of the first PMOS transistor, wherein a gate of the first PMOS transistor is coupled to a gate of the first NMOS transistor;
a second PMOS transistor having a source coupled to the always-on current source and to the boost current source;
a second NMOS transistor having a drain coupled to a drain of the second PMOS transistor, wherein a gate of the second PMOS transistor is coupled to a gate of the second NMOS transistor; and
a third NMOS transistor having a source coupled to ground, a gate coupled to the drain of the second NMOS transistor, and a drain coupled to a source of the first NMOS transistor and to a source of the second NMOS transistor.
   Clause 18. The comparator of clause 17, further comprising:
an inverter configured to invert a voltage of the drain of the first PMOS transistor to provide a comparator output signal.
   Clause 19. The comparator of any of clauses 17-18, further comprising:
a fourth NMOS transistor having a drain coupled to the source of the first NMOS transistor and to the source of the second NMOS transistor and having a gate coupled to the drain of the second NMOS transistor; and
a second switch coupled between a source of the fourth NMOS transistor and ground.
   Clause 20. The comparator of clause 19, wherein a size of the fourth NMOS transistor is greater than a size of the third NMOS transistor.

As those of some skill in this art will by now appreciate and depending on the particular application at hand, many modifications, substitutions and variations can be made in and to the materials, apparatus, configurations and methods of use of the devices of the present disclosure without departing from the scope thereof as defined by the appended claims. In light of this, the scope of the present disclosure should not be limited to that of the particular implementations illustrated and described herein, as they are merely by way of some examples thereof, but rather, should be fully commensurate with that of the claims appended hereafter and their functional equivalents.

What is claimed is:

1. A comparator system, comprising:
a ramp signal generator configured to periodically generate a ramp signal;
an auxiliary comparator configured to assert an enable signal in response to the ramp signal being greater than a duty cycle voltage;
a main comparator configured to assert a comparator output signal in response to the ramp signal being greater than a threshold voltage that is greater than the duty cycle voltage, wherein the main comparator includes:
an always-on current source configured to conduct a bias current throughout a period of the ramp signal; and
a boost current source configured to conduct a boost current only while the enable signal is asserted.

2. The comparator system of claim 1, wherein the main comparator further includes:
a power supply node for a power supply voltage; and
a first switch configured coupled to the power supply node and configured to close only while the enable signal is asserted, wherein the always-on current source is coupled to the power supply node and wherein the first switch is coupled between the power supply node and the boost current source.

3. The comparator system of claim 2, wherein the main comparator further includes:
a first self-biased transistor having a source coupled to ground;
a first pair of transistors coupled in series between a current source output node of both the always-on current source and the boost current source and a drain of the first self-biased transistor; and
a second pair of transistors coupled in series between the current source output node and the drain of the first self-biased transistor, wherein a gate of the first self-biased transistor is coupled to a node between the transistors in the second pair of transistors.

4. The comparator system of claim 3, wherein the main comparator further comprises:
a second self-biased transistor having a drain coupled to the drain of the first self-biased transistor and having a gate coupled to the node between the transistors in the second pair of transistors; and
a second switch coupled between a source of the second self-biased transistor and ground, wherein the second switch is configured to close only while the enable signal is asserted.

5. The comparator system of claim 4, wherein the first pair of transistors comprises:
a first p-type metal-oxide semiconductor (PMOS) transistor having a source coupled to the current source output node; and
a first n-type metal-oxide semiconductor (NMOS) transistor having a drain coupled to a drain of the first PMOS transistor and having a source coupled to a drain of the first self-biased transistor and to a drain of the second self-biased transistor.

6. The comparator system of claim 4, wherein the second pair of transistors comprises:
a second PMOS transistor having a source coupled to the current source output node; and
a second NMOS transistor having a drain coupled to a drain of the second PMOS transistor and having a source coupled to a drain of the first self-biased transistor and to a drain of the second self-biased transistor.

7. The comparator system of claim 5, wherein a gate of the first PMOS transistor and a gate of the first NMOS transistor are both coupled to a node for the ramp signal.

8. The comparator system of claim 6, wherein a gate of the second PMOS transistor and a gate of the second NMOS transistor are both coupled to a node for the duty cycle voltage.

9. The comparator system of claim 5, wherein the main comparator further comprises:
an inverter configured to invert a voltage of the drain of the first PMOS transistor to provide the comparator output signal.

10. The comparator system of claim 1, further comprising:
a set-reset latch configured to reset a clock signal to a current digital-to-analog converter in response to an assertion of the comparator output signal.

11. The comparator system of claim 10, wherein the current digital-to-analog converter in included in a sigma-delta analog-to-digital converter.

12. The comparator system of claim 1, wherein the comparator system is included within a cellular telephone.

13. A method of operation for a comparator, comprising:
periodically generating a ramp signal;
conducting a bias current through the comparator throughout a period of the ramp signal;
conducting a boost current through the comparator in response to the ramp signal being greater than a duty cycle voltage; and
asserting an output signal of the comparator in response to the ramp signal being greater than a threshold voltage that is greater than the duty cycle voltage.

14. The method of claim 13, further comprising:
resetting a clock to a current digital-to-analog converter in a sigma-delta analog digital converter responsive to an assertion of the output signal of the comparator.

15. The method of claim 13, further comprising:
stopping a conduction of the boost current through the comparator in response to the ramp signal being greater than the threshold voltage.

16. The method of claim 13, wherein the boost current is larger than the bias current.

17. A comparator comprising:
a power supply node for a power supply voltage;
an always-on current source coupled to the power supply node;
a first switch coupled to the power supply node;
a boost current source coupled to the first switch;
a first PMOS transistor having a source coupled to the always-on current source and to the boost current source;
a first NMOS transistor having a drain coupled to a drain of the first PMOS transistor, wherein a gate of the first PMOS transistor is coupled to a gate of the first NMOS transistor;
a second PMOS transistor having a source coupled to the always-on current source and to the boost current source;
a second NMOS transistor having a drain coupled to a drain of the second PMOS transistor, wherein a gate of the second PMOS transistor is coupled to a gate of the second NMOS transistor; and
a third NMOS transistor having a source coupled to ground, a gate coupled to the drain of the second NMOS transistor, and a drain coupled to a source of the first NMOS transistor and to a source of the second NMOS transistor.

18. The comparator of claim 17, further comprising:
an inverter configured to invert a voltage of the drain of the first PMOS transistor to provide a comparator output signal.

19. The comparator of claim 17, further comprising:
a fourth NMOS transistor having a drain coupled to the source of the first NMOS transistor and to the source of the second NMOS transistor and having a gate coupled to the drain of the second NMOS transistor; and
a second switch coupled between a source of the fourth NMOS transistor and ground.

20. The comparator of claim 19, wherein a size of the fourth NMOS transistor is greater than a size of the third NMOS transistor.
